(19) United States
(12) Patent Application Publication
(10) Pub. No.: US 2026/0130059 A1
(43) Pub. Date: May 7, 2026

(54) DISPLAY PANEL AND ELECTRONIC DEVICE

(71) Applicants: Visionox Technology Inc., Kunshan (CN); Hefei Visionox Technology Co., Ltd., Hefei (CN)

(72) Inventors: Xingfeng REN, Kunshan (CN); Yuan YAO, Hefei (CN); Lin HUANG, Hefei (CN); Jui-Yang TSAI, Hefei (CN); Chung-Chun LEE, Kunshan (CN); Peng QIN, Kunshan (CN)

(73) Assignees: Visionox Technology Inc., Kunshan (CN); Hefei Visionox Technology Co., Ltd., Hefei (CN)

(21) Appl. No.: 19/378,259

(22) Filed: Nov. 3, 2025

(30) Foreign Application Priority Data
Nov. 6, 2024 (CN) 202411574143.3

(51) Int. Cl. H10K 59/122; H10K 59/80

(52) U.S. Cl. CPC H10K 59/122; H10K 59/873

(57) ABSTRACT

The present application provides a display panel and an electronic device. The display panel includes a substrate and a pixel defining layer. The pixel defining layer is disposed on one side of the substrate and has pixel openings. Sidewalls of the pixel openings are continuously arranged, and in a direction away from the substrate, the sidewalls of the pixel openings successively has a first taper angle and a second taper angle, the first taper angle and the second taper angle are angles formed between a tangent line at a point on the sidewalls of the pixel openings and a plane where the substrate is located, and the second taper angle is greater than or equal to the first taper angle.

### CROSS-REFERENCE TO RELATED APPLICATIONS

The present application claims priority to the Chinese Patent Application No. 202411574143.3, filed on Nov. 6, 2024, and the entire contents of the aforementioned application are hereby incorporated by reference in its entirety.

### FIELD

The present application relates to the field of display technology, and more particularly to a display panel and an electronic device

### BACKGROUND

Embodiments of the present application provide a display panel, and the display panel includes: a substrate; a pixel defining layer, disposed on one side of the substrate and provided with a plurality of pixel openings, and sidewalls of the pixel openings are arranged continuously, and in a direction away from the substrate, the sidewalls of the pixel openings sequentially have a first taper angle and a second taper angle, and the first taper angle and the second taper angle are angles formed between a tangent line at a point on the sidewall of the pixel opening and a plane where the substrate is located, and the second taper angle is greater than or equal to the first taper angle; an isolation structure, disposed on a side of the pixel defining layer away from the substrate, and the isolation structure is enclosed to form isolation openings, and the isolation openings communicate with the pixel openings.

In some embodiments, the present application also provides a display panel, and the display panel includes: a substrate; a pixel defining layer, disposed on one side of the substrate; and the pixel defining layer includes pixel openings, and in a direction away from the substrate, the pixel defining layer includes a plurality of stacked pixel defining sublayers, and etching selectivity ratios of materials of the multiple pixel defining sublayers decrease in sequence in the direction away from the substrate; an isolation structure, disposed on a side of the pixel defining layer away from the substrate, and the isolation structure encloses to form isolation openings, and the isolation openings communicate with the pixel openings.

In some embodiments, the present application also provides an electronic device, and the electronic device includes the display panel disclosed in the present application, or includes a display panel prepared by the preparation method of the display panel disclosed in the present application.

The display panel and electronic device provided by the present application, by setting the second taper angle on the sidewall of the pixel opening to be greater than or equal to the first taper angle, can avoid damaging the light-emitting unit during the patterning process of the light-emitting unit, thereby improving the display effect of the display panel.

### BRIEF DESCRIPTION OF THE DRAWINGS

To more clearly illustrate the embodiments of the present application, a brief introduction will be given to the drawings that need to be used in the embodiments. It should be understood that the following drawings only show some embodiments of the present application and therefore should not be considered as limiting the scope.

FIG. 1 is a cross-sectional view of a display panel in the related technology provided by embodiments of the present application;

FIG. 2a is one of the cross-sectional views showing the inclined arrangement of the pixel opening of the display panel provided by embodiments of the present application;

FIG. 2b is another cross-sectional view showing the inclined arrangement of the pixel opening of the display panel provided by embodiments of the present application;

FIG. 3a is one of the cross-sectional views showing the pixel defining layer including a stacked first pixel defining sublayer, second pixel defining sublayer and third pixel defining sublayer of the display panel provided by embodiments of the present application;

FIG. 3b is another cross-sectional view showing the pixel defining layer including a stacked first pixel defining sublayer, second pixel defining sublayer and third pixel defining sublayer of the display panel provided by embodiments of the present application;

FIG. 3c is a top view of a first pixel sub-opening, a second pixel sub-opening and a third pixel sub-opening provided by embodiments of the present application;

FIG. 4 is a cross-sectional view of the display panel including an isolation structure provided by embodiments of the present application;

FIG. 5 is a cross-sectional view of the display panel including an encapsulation unit provided by embodiments of the present application;

FIG. 6 is a cross-sectional view of the display panel including a second encapsulation layer and a third encapsulation layer provided by embodiments of the present application;

FIG. 7 is a flow diagram of a method for preparing a display panel provided by embodiments of the present application;

FIG. 8 is a cross-sectional view showing the formation of a first electrode layer at one side of the substrate provided by embodiments of the present application;

FIG. 9 is a cross-sectional view showing the successive formation of a stacked first pixel defining material sublayer, second pixel defining material sublayer and third pixel defining material sublayer at one side of the substrate provided by embodiments of the present application;

FIG. 10 is a cross-sectional view showing the formation of a patterned photoresist protection layer at a side of the third pixel defining material sublayer away from the substrate provided by embodiments of the present application;

FIG. 11 is a cross-sectional view after removing the third pixel defining material sublayer not covered by the photoresist protection layer using a first etching energy provided by embodiments of the present application;

FIG. 12 is a cross-sectional view after removing the second pixel defining material sublayer exposed by the first opening using a second etching energy provided by embodiments of the present application;

FIG. 13 is a cross-sectional view after removing the first pixel defining material sublayer exposed by the second opening using a third etching energy provided by embodiments of the present application;

FIG. 14 is a cross-sectional view after removing the photoresist protection layer provided by embodiments of the present application;

FIG. 15 is a cross-sectional view showing the formation of an isolation structure at a side of the pixel defining layer away from the substrate provided by embodiments of the present application;

FIG. 16 is a cross-sectional view showing the formation of a light-emitting material layer of a first light-emitting unit in a first isolation opening provided by embodiments of the present application;

FIG. 17 is a cross-sectional view showing the successive formation of a second electrode material layer and a first encapsulation material layer at a side of the light-emitting material layer of the first light-emitting unit away from the substrate provided by embodiments of the present application;

FIG. 18 is a cross-sectional view showing the formation of a first etching barrier layer at a side of the first encapsulation material layer of the first light-emitting unit away from the substrate in the first isolation opening provided by embodiments of the present application;

FIG. 19 is a cross-sectional view after removing the first encapsulation material layer, the second electrode material layer and the light-emitting material layer of the first light-emitting unit not covered by the first etching barrier layer provided by embodiments of the present application;

FIG. 20 is a cross-sectional view showing the formation of a light-emitting material layer of a second light-emitting unit in a second isolation opening provided by embodiments of the present application;

FIG. 21 is a cross-sectional view showing the successive formation of a second electrode material layer and a first encapsulation material layer at a side of the light-emitting material layer of the second light-emitting unit away from the substrate provided by embodiments of the present application;

FIG. 22 is a cross-sectional view showing the formation of a second etching barrier layer at a side of the first encapsulation material layer of the second light-emitting unit away from the substrate in the second isolation opening provided by embodiments of the present application.

List of reference signs: 1, substrate; 2, pixel defining layer; 201, pixel opening; 202, step; 203, recess; 3, first electrode; 4, first pixel defining sublayer; 41, first pixel sub-opening; 5, second pixel defining sublayer; 51, second pixel sub-opening; 6, third pixel defining sublayer; 61, third pixel sub-opening; 7, light-emitting portion; 8, second electrode; 9, isolation structure; 901, isolation opening; 9011, first isolation opening; 9012, second isolation opening; 91, first isolation portion; 92, second isolation portion; 93, third isolation portion; 10, encapsulation unit; 101, first encapsulation unit; 102, second encapsulation unit; 11, second encapsulation layer; 12, third encapsulation layer; 13, first pixel defining material sublayer; 14, second pixel defining material sublayer; 141, second opening; 15, third pixel defining material sublayer; 151, first opening; 16, photoresist protection layer; 17, light-emitting material layer; 18, second electrode material layer; 19, first encapsulation material layer; 20, first etching barrier layer; 21, second etching barrier layer; 22, light-emitting unit.

### DETAILED DESCRIPTION OF THE EMBODIMENTS

To make the embodiments of the present application clearer, the embodiments of the present application will be described clearly and completely in conjunction with the drawings in the embodiments of the present application. Obviously, the described embodiments are only a part of the embodiments of the present application, rather than all embodiments. Generally, the components of the embodiments of the present application described and shown in the drawings herein can be arranged and designed in various different configurations.

Therefore, the following detailed description of the embodiments of the present application provided in the drawings is not intended to limit the scope of the present application being claimed, but merely represents selected embodiments of the present application.

It should be noted that: similar reference numerals and letters in the following drawings indicate similar items, therefore, once an item is defined in one drawing, it does not need to be further defined and explained in subsequent drawings.

In the description of the present application, it should be noted that terms such as “center”, “up”, “down”, “vertical”, “horizontal”, “inner”, “outer” and other directional or positional relationships are based on the directional or positional relationships shown in the drawings, or the conventional directional or positional relationships when the invention product is in use, and are only for the convenience of describing the present application and simplifying the description, and do not indicate or imply that the referred device or element must have a specific orientation, be constructed or operated in a specific orientation, and therefore should not be understood as limitations to the present application. Furthermore, terms such as “first”, “second”, “third” are only used for distinguishing description and should not be understood as indicating or implying relative importance.

It should be noted that different features in the embodiments of the present application can be combined with each other when there is no conflict.

Increasing the density of light-emitting units (i.e., pixel density) in display panels is an important way to improve display effect. However, display panels currently made using Fine Metal Mask (FMM) technology cannot further increase the density of light-emitting units due to limitations. After long-term research, the inventors found that to solve the problem of being unable to further increase the density of light-emitting units, isolation structures are set in some display panels. When depositing the light-emitting functional layer and the second electrode in a full layer, the light-emitting functional layer and the second electrode can be disconnected at the isolation structure. Different colored light-emitting units can be formed in different isolation openings through multiple deposition and multiple etching processes (i.e., light-emitting unit patterning).

Among them, patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, CN117500332A record related embodiments of isolation structures, the contents of which are incorporated by reference into the present application for reference.

Please refer to FIG. 1, the display panel in the related technology includes a substrate 1 and a pixel defining layer 2 disposed on one side of the substrate 1. The pixel defining layer 2 has pixel openings 201, and a sidewall of any one of the pixel openings 201 has a step 202. When forming a preceding light-emitting unit (the light-emitting unit prepared first), the film continuity of a second electrode material layer of the preceding light-emitting unit is poor at the step 202 of the pixel opening 201 for a subsequent light-emitting unit, and the second electrode material layer of the preceding light-emitting unit cannot effectively protect the pixel defining layer 2 corresponding to the subsequent light-emitting unit (the light-emitting unit prepared later) at the step 202 of the pixel opening 201.

Thus, during the patterning process of the preceding light-emitting unit, recesses 203 may form on the pixel defining layer 2 corresponding to the subsequent light-emitting unit, and the first electrode 3 (anode) of the subsequent light-emitting unit may be damaged, ultimately affecting the display effect of the display panel.

To solve the problems mentioned above, the inventors innovatively designed the following embodiments. The specific implementation schemes of the present application will be described in detail in conjunction with the drawings below. It should be noted that the defects existing in the above prior art solutions were all concluded by the inventors after practice and careful research. Therefore, both the discovery process of the above problems and the solutions proposed by this embodiment for the above problems should be considered as contributions made by the inventors to the present application during the invention process.

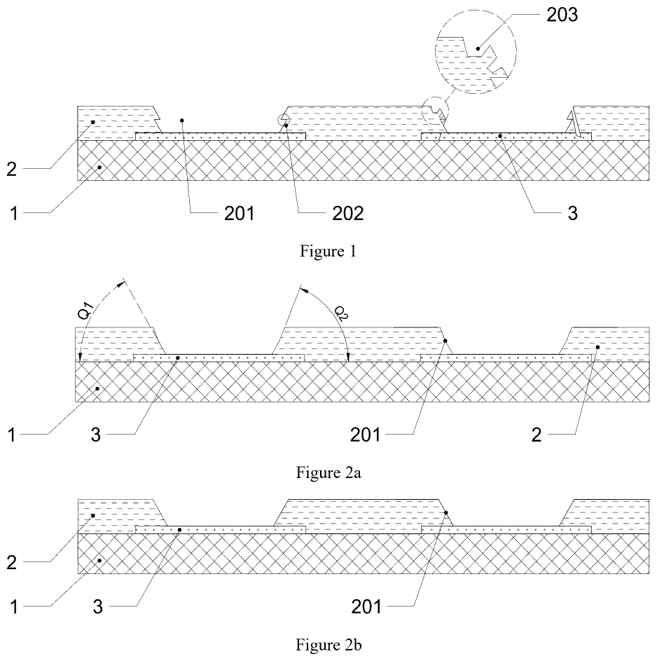

Please refer to FIG. 2a, this embodiment provides a display panel, which includes a substrate 1 and a pixel defining layer 2.

The substrate 1 may include a base substrate and multiple driving units disposed at one side of the base substrate, and each driving unit may include one or more semiconductor switching devices. The semiconductor switching devices can be formed by cooperation of multiple film layers in the substrate 1, for example, the semiconductor switching device can be a thin film transistor formed by cooperation of multiple film layers.

The pixel defining layer 2 is disposed at one side of the substrate 1 and has a plurality of pixel openings 201. A sidewall of any one of the pixel openings 201 is continuously arranged, and the continuous arrangement herein means having a continuous slope without a cliff or an undercut situation. Along a direction away from the substrate 1, the sidewall of any one of the pixel openings 201 successively has a first taper angle Q1 and a second taper angle Q2, and the first taper angle Q1 and the second taper angle Q2 are angles formed between a tangent line at a point on the sidewall of the pixel opening 201 and a plane where the substrate 1 is located. The positions of the first taper angle Q1 and the second taper angle Q2 are not fixed, and the second taper angle Q2 is greater than or equal to the first taper angle Q1.

In some embodiments, please refer to FIG. 2a again, the second taper angle Q2 is greater than the first taper angle Q1.

In other embodiments, please refer to FIG. 2b, the second taper angle Q2 equals the first taper angle Q1.

Since the second taper angle Q2 on the sidewall of the pixel opening 201 is greater than or equal to the first taper angle Q1, during the formation process of the preceding light-emitting unit of the display panel, a second electrode material layer of the preceding light-emitting unit can form a continuous and uniform film on the sidewall of the pixel opening 201 corresponding to the subsequent light-emitting unit, thereby enabling the second electrode material layer of the preceding light-emitting unit to more effectively protect the pixel defining layer 2 corresponding to the subsequent light-emitting unit.

During the patterning process of the preceding light-emitting unit, recesses 203 are not easily formed on the pixel defining layer 2 corresponding to the subsequent light-emitting unit, and the first electrode 3 of the subsequent light-emitting unit is not easily damaged, thereby improving the display effect of the display panel.

Based on the above design, this embodiment can improve the display effect of the display panel by setting the second taper angle Q2 on the sidewall of the pixel opening 201 to be greater than or equal to the first taper angle Q1, as the light-emitting unit is not easily damaged during the patterning process.

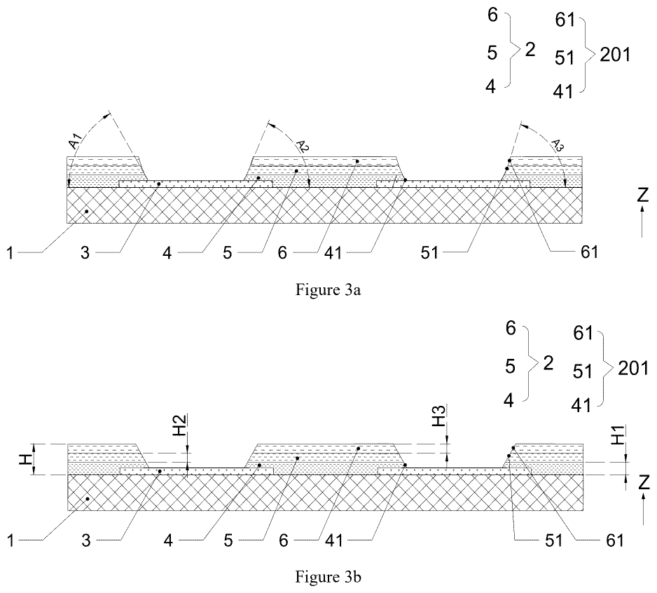

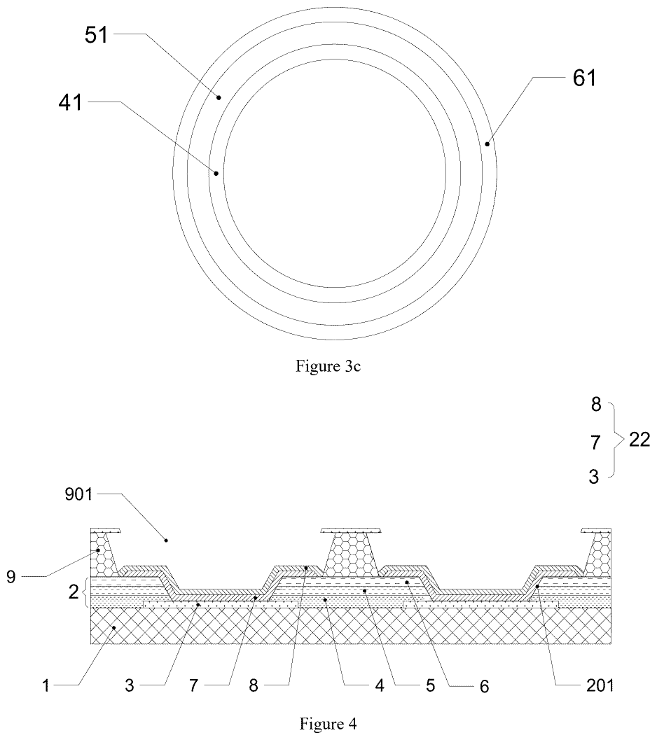

In some embodiments, please refer to FIG. 3a, the pixel defining layer 2 includes a first pixel defining sublayer 4 and a second pixel defining sublayer 5 arranged along the direction away from the substrate 1. The first pixel defining sublayer 4 has a plurality of first pixel sub-openings 41, the second pixel defining sublayer 5 has a plurality of second pixel sub-openings 51, a sidewall of any one of the first pixel sub-openings 41 has a first sub-taper angle A1, a sidewall of any one of the second pixel sub-openings 51 has a second sub-taper angle A2, and the second sub-taper angle A2 on the second pixel defining sublayer 5 is greater than or equal to the first sub-taper angle A1 on the first pixel defining sublayer 4.

In some embodiments, the pixel defining layer 2 further includes a third pixel defining sublayer 6 disposed at a side of the second pixel defining sublayer 5 away from the substrate 1. The third pixel defining sublayer 6 has a plurality of third pixel sub-openings 61, a sidewall of any one of the third pixel sub-openings 61 has a third sub-taper angle A3, and the third sub-taper angle A3 on the third pixel defining sublayer 6 is greater than or equal to the second sub-taper angle A2 on the second pixel defining sublayer 5.

The first sub-taper angle A1 is an angle formed between a tangent line at a point on the sidewall of the first pixel sub-opening 41 and a plane where the substrate 1 is located, the second sub-taper angle A2 is an angle formed between a tangent line at a point on the sidewall of the second pixel sub-opening 51 and the plane where the substrate 1 is located, and the third sub-taper angle A3 is an angle formed between a tangent line at a point on the sidewall of the third pixel sub-opening 61 and the plane where the substrate 1 is located.

In some embodiments, please refer to FIG. 3a again, the second sub-taper angle A2 is greater than the first sub-taper angle A1, and the third sub-taper angle A3 is greater than the second sub-taper angle A2.

In other embodiments, please refer to FIG. 3b, the second sub-taper angle A2 equals the first sub-taper angle A1, and the third sub-taper angle A3 equals the second sub-taper angle A2.

The pixel openings 201 include the first pixel sub-openings 41, the second pixel sub-openings 51 and the third pixel sub-openings 61. By setting the pixel defining layer 2 as a successively stacked first pixel defining sublayer 4, second pixel defining sublayer 5 and third pixel defining sublayer 6, it becomes easier to make the sidewall of the pixel openings 201 a complete continuous surface.

In some embodiments, an orthographic projection of a side of the first pixel sub-opening 41 away from the substrate 1 on the substrate 1 coincides with an orthographic projection of a side of the second pixel sub-opening 51 close to the substrate 1 on the substrate 1.

In some embodiments, an orthographic projection of a side of the second pixel sub-opening 51 away from the substrate 1 on the substrate 1 coincides with an orthographic projection of a side of the third pixel sub-opening 61 close to the substrate 1 on the substrate 1.

In some embodiments, please refer to FIG. 3b and FIG. 3c, along a thickness direction Z of the substrate 1, an area of the second pixel sub-opening 51 covers an area of the first pixel sub-opening 41, and an area of the third pixel sub-opening 61 covers an area of the second pixel sub-opening 51.

The sidewalls of the first pixel sub-openings 41, the second pixel sub-openings 51, and the third pixel sub-openings 61 are located on the same continuous surface, therefore, the sidewall of the pixel opening 201 is a complete continuous surface. This allows the second electrode material layer of the preceding light-emitting unit to form a more continuous and uniform film on the sidewall of the pixel opening 201 corresponding to the subsequent light-emitting unit, thereby further improving the protection effect of the second electrode material layer of the preceding light-emitting unit on the pixel defining layer 2 and first electrode 3 and other film layers corresponding to the subsequent light-emitting unit.

In some embodiments, please refer to FIG. 4, the display panel further includes an isolation structure 9 disposed at a side of the pixel defining layer 2 away from the substrate 1. The isolation structure 9 is enclosed to form isolation openings 901, and the isolation openings 901 communicates with the pixel openings 201.

In some embodiments, the display panel further includes a light-emitting unit 22 at least partially disposed in the isolation opening 901. The light-emitting unit 22 includes a first electrode 3, a light-emitting portion 7 and a second electrode 8 stacked successively along the direction away from the substrate 1, and the pixel opening 201 exposes a portion of the first electrode 3.

The setting of the isolation structure 9 enables the display panel to form film layers of the light-emitting unit 22 of different colors in different isolation openings 901 without requiring a fine metal mask. When forming a light-emitting material layer, the light-emitting material layer will be separated by the isolation structure 9 to form multiple spaced light-emitting portions 7. When forming a second electrode material layer, the second electrode material layer will be separated by the isolation structure 9 to form multiple spaced second electrodes 8. The isolation structure 9 includes a conductive material, and the second electrode 8 is electrically connected to the isolation structure 9. One first electrode 3, one light-emitting portion 7 and one second electrode 8 form one light-emitting unit 22. Among them, the first electrode 3 can be an anode, and the second electrode 8 can be a cathode.

Thus, different light-emitting units 22 can be mutually independent, thereby improving crosstalk between adjacent light-emitting units 22 and enhancing the display effect of the display panel. Meanwhile, due to the presence of the isolation structure 9, the light-emitting material layer and the second electrode material layer of each color light-emitting unit 22 in the display panel can be first prepared in a full surface and then patterned, thereby eliminating the need for fine metal masks and reducing the preparation cost of the display panel.

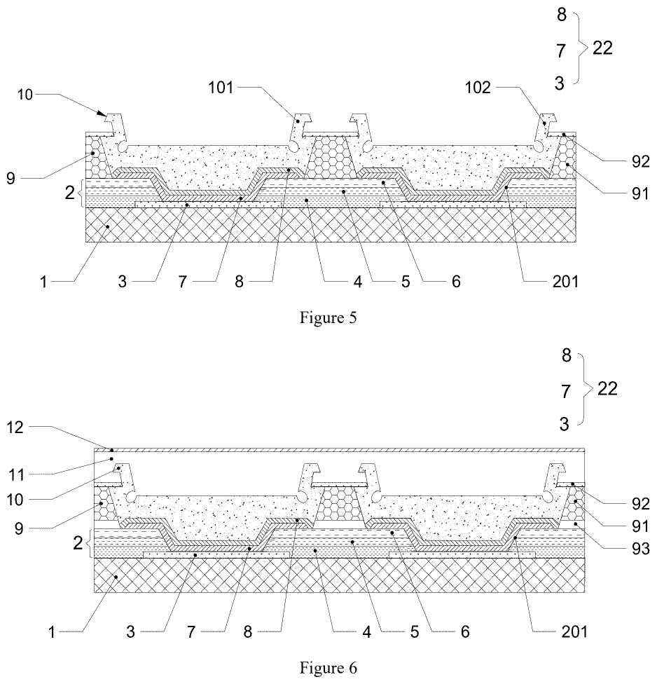

In some embodiments, please refer to FIG. 5, the display panel further includes an encapsulation unit 10 disposed at a side of the light-emitting unit 22 away from the substrate 1. At least a portion of the encapsulation unit 10 extends from a side surface of the isolation structure 9 facing the isolation opening 901 to a side of the isolation structure 9 away from the substrate 1. Adjacent encapsulation units 10 are spaced apart or overlapped with each other at the side of the isolation structure 9 away from the substrate 1, and there is a gap between the encapsulation unit 10 disposed at the side of the isolation structure 9 away from the substrate 1 and the side of the isolation structure 9 away from the substrate 1.

During the patterning process of the light-emitting unit 22, a first encapsulation layer breaks at the isolation structure 9 to form an encapsulation unit 10. The encapsulation unit 10 can completely independently encapsulate the corresponding light-emitting unit 22, thereby improving the display characteristics of the display panel.

In some embodiments, please refer to FIG. 4 again, etching selectivity ratios of materials of the first pixel defining sublayer 4, the second pixel defining sublayer 5 and the third pixel defining sublayer 6 decrease successively.

The etching selectivity ratio of the material of the second pixel defining sublayer 5 is between those of the first pixel defining sublayer 4 and the third pixel defining sublayer 6. The second pixel defining sublayer 5 serves as a transition, which can relieve the stress difference between the first pixel defining sublayer 4 and the third pixel defining sublayer 6, allowing the sidewall of the first pixel sub-opening 41 to smoothly transition to the sidewall of the third pixel sub-opening 61 through the sidewall of the second pixel sub-opening 51. Thus, when patterning the pixel defining layer 2, it becomes easier to make the sidewall of the pixel opening 201 inclined, forming a complete inclined surface.

Additionally, the etching selectivity ratio of the material of the third pixel defining sublayer 6 is relatively small. During the patterning process of the light-emitting unit 22, recesses 203 are not easily formed at the side of the third pixel defining sublayer 6 away from the substrate 1, allowing the side of the third pixel defining sublayer 6 away from the substrate 1 to be set flat, thereby enabling more effective connection between the second electrode 8 of the light-emitting unit 22 and the isolation structure 9, which can further improve the display effect of the display panel.

In some embodiments, along the direction from the first pixel defining sublayer 4 to the third pixel defining sublayer 6, the etching selectivity ratio of the material of the second pixel defining sublayer 5 decreases gradually.

Thus, the sidewall of the second pixel sub-opening 51 formed on the second pixel defining sublayer 5 is inclined more smoothly, the transition effect of the second pixel defining sublayer 5 between the first pixel defining sublayer 4 and the third pixel defining sublayer 6 is better, and ultimately the sidewall of the pixel opening 201 can be inclined more smoothly.

In some embodiments, densities of the first pixel defining sublayer 4, the second pixel defining sublayer 5 and the third pixel defining sublayer 6 decrease successively. Density can be further explained as the ability to isolate moisture, where a higher density means a stronger ability to isolate moisture, and vice versa.

The substrate 1 includes a base substrate and film layers such as a planarization layer at one side of the base substrate, and the material of the planarization layer includes an organic material. Moisture easily transfers in organic materials, and although the pixel defining layer 2 includes an inorganic material through which moisture does not easily transfer, some moisture may still transfer through the pixel defining layer 2 to the isolation structure 9. When the material of the isolation structure 9 contacts moisture, it can easily affect the morphology of the isolation structure 9, such as forming uneven structures on the surface of the isolation structure 9, ultimately affecting the connection effect between the second electrode 8 and the isolation structure 9.

In this embodiment, since the density of the first pixel defining sublayer 4 is relatively high, the first pixel defining sublayer 4 can more effectively block moisture from the film layers of the substrate 1 from dispersing toward the isolation structure 9, thereby improving the problem of moisture affecting the morphology of the isolation structure 9, and ultimately further improving the connection effect between the second electrode 8 and the isolation structure 9.

In some embodiments, a material of the first pixel defining sublayer 4 includes silicon nitride, a material of the second pixel defining sublayer 5 includes silicon oxynitride, and a material of the third pixel defining sublayer 6 includes silicon oxide.

In some embodiments, along the direction from the first pixel defining sublayer 4 to the third pixel defining sublayer 6, at least two layers in the pixel defining layer 2 include an oxygen element, and a content of the oxygen element increases gradually.

In some embodiments, along the direction from the first pixel defining sublayer 4 to the third pixel defining sublayer 6, at least two layers in the pixel defining layer 2 include a nitrogen element, and a content of the nitrogen element decreases gradually.

Since the parts of the second pixel defining sublayer 5 closer to the third pixel defining sublayer 6 have a higher oxygen element content, these parts have properties more similar to those of the third pixel defining sublayer 6.

Since the parts of the second pixel defining sublayer 5 closer to the first pixel defining sublayer 4 have a higher nitrogen element content, these parts have properties more similar to those of the first pixel defining sublayer 4.

Thus, this can further improve the transition effect of the second pixel defining sublayer 5 between the first pixel defining sublayer 4 and the third pixel defining sublayer 6, ultimately making the sidewall of the pixel opening 201 incline more smoothly.

In some embodiments, please refer to FIG. 3b again, along the thickness direction Z of the substrate 1, a thickness H of the pixel defining layer 2 is greater than or equal to 2000 Å and less than or equal to 6000 Å, for example, the thickness H can be 2000 Å, 2500 Å, 3000 Å, 3500 Å, 4000 Å, 4500 Å, 5000 Å, 5500 Å or 6000 Å, etc. Reasonably setting the thickness H can improve both the protection effect of the pixel defining layer 2 on the first electrode 3 and the connection effect between the second electrode 8 and the isolation structure 9.

In one embodiment, along the thickness direction Z of the substrate 1, a thickness H1 of the first pixel defining sublayer 4 is greater than or equal to 600 Å and less than or equal to 3000 Å, for example, the thickness H1 can be 600 Å, 1000 Å, 1200 Å, 1500 Å, 2000 Å, 2500 Å, 2800 Å or 3000 Å, etc. Reasonably setting the thickness H1 can improve the effect of the first pixel defining sublayer 4 in blocking moisture from the substrate 1.

In one embodiment, along the thickness direction Z of the substrate 1, a thickness H2 of the second pixel defining sublayer 5 is greater than or equal to 600 Å and less than or equal to 3000 Å, for example, the thickness H2 can be 600 Å, 1000 Å, 1200 Å, 1500 Å, 2000 Å, 2500 Å, 2800 Å or 3000 Å, etc. Reasonably setting the thickness H2 can improve the transition effect of the second pixel defining sublayer 5 between the first pixel defining sublayer 4 and the third pixel defining sublayer 6, making the sidewall of the pixel opening 201 incline more smoothly.

In one embodiment, along the thickness direction Z of the substrate 1, a thickness H3 of the third pixel defining sublayer 6 is greater than or equal to 600 Å and less than or equal to 3000 Å, for example, the thickness H3 can be 600 Å, 1000 Å, 1200 Å, 1500 Å, 2000 Å, 2500 Å, 2800 Å or 3000 Å, etc. Reasonably setting the thickness H3 can improve the protection effect of the third pixel defining sublayer 6 on the first electrode 3.

In some embodiments, please refer to FIG. 6, the display panel further includes a second encapsulation layer 11 disposed at a side of the encapsulation unit 10 away from the substrate 1 and a third encapsulation layer 12 disposed at a side of the second encapsulation layer 11 away from the substrate 1. Materials of both the encapsulation unit 10 and the third encapsulation layer 12 include inorganic materials, and a material of the second encapsulation layer 11 includes an organic material.

For example, the first encapsulation layer and the third encapsulation layer 12 can be formed by Chemical Vapor Deposition (CVD), and the second encapsulation layer 11 can be formed by Ink-jet Printing (IJP). The second encapsulation layer 11 and the third encapsulation layer 12 can provide a better encapsulation effect for the light-emitting unit 22, thereby further improving the encapsulation quality of the display panel.

In one embodiment, please refer to FIG. 5 again, the isolation structure 9 includes a first isolation portion 91 and a second isolation portion 92 stacked successively along the direction away from the substrate 1, and the second isolation portion 92 is disposed on the first isolation portion 91 and extends outward along a sidewall of the first isolation portion 91.

Since the second isolation portion 92 is located at a side of the first isolation portion 91 away from the substrate 1, and in a plane parallel to the plane where the substrate 1 is located, a horizontal width of the second isolation portion 92 is greater than a horizontal width of the first isolation portion 91, therefore the second isolation portion 92 will cause the light-emitting material layer and the second electrode material layer to break at the isolation structure 9. Thus, the isolation structure 9 formed by the first isolation portion 91 and the second isolation portion 92 can more easily enable independent encapsulation of each light-emitting unit 22, thereby improving the encapsulation yield of the display panel.

Please refer to FIG. 5 again, the second electrode 8 is electrically connected to the first isolation portion 91; the first isolation portion 91 includes a conductive material, and the second electrode 8 corresponding to the light-emitting unit 22 extends to contact with the sidewall of the first isolation portion 91 to achieve an electrical connection between the second electrode 8 corresponding to the light-emitting unit 22 and the first isolation portion 91.

Please refer to FIG. 6 again, the isolation structure 9 further includes a third isolation portion 93 disposed at a side of the first isolation portion 91 facing the substrate 1, and the second electrode 8 is electrically connected to the third isolation portion 93.

The third isolation portion 93 includes a conductive material, and the second electrode 8 corresponding to the light-emitting unit 22 extends to contact with the sidewall of the third isolation portion 93 to achieve an electrical connection between the second electrode 8 corresponding to the light-emitting unit 22 and the third isolation portion 93.

In one embodiment, a material of the third isolation portion 93 includes molybdenum; and/or, a material of the first isolation portion 91 includes aluminum; and/or, a material of the second isolation portion 92 includes titanium. Thus, when the isolation structure 9 separates the second electrode material layer 18 into second electrodes 8, the second electrode 8 can more easily electrically connect with the first isolation portion 91 and/or the third isolation portion 93.

An orthographic projection of the light-emitting portion 7 on the substrate 1 is located outside orthographic projections of the third isolation portion 93 and the first isolation portion 91 on the substrate 1. Thus, the light-emitting portion 7 does not connect with the isolation structure 9, thereby effectively improving the crosstalk problem between light-emitting units 22.

In some embodiments, please refer to FIG. 4 again, the present application also provides another display panel, and the display panel includes a substrate 1, a pixel defining layer 2 and an isolation structure 9.

The pixel defining layer 2 is disposed at one side of the substrate 1; the pixel defining layer 2 includes pixel openings 201, and along a direction away from the substrate 1, the pixel defining layer 2 includes multiple pixel defining sublayers stacked successively, and etching selectivity ratios of materials of the multiple pixel defining sublayers decrease successively along the direction away from the substrate 1. The multiple pixel defining sublayers successively include a first pixel defining sublayer, a second pixel defining sublayer and a third pixel defining sublayer along the direction away from the substrate, and the first pixel defining sublayer is used for blocking moisture, the second pixel defining sublayer is used for buffering between upper and lower film layers, and the third pixel defining sublayer is used for preventing over-etching.

The isolation structure 9 is disposed at a side of the pixel defining layer 2 away from the substrate 1, and the isolation structure 9 is enclosed to form isolation openings 901, and the isolation openings 901 communicates with the pixel openings 201.

Since the etching selectivity ratios of materials of the multiple pixel defining sublayers in the pixel defining layer 2 decrease successively along the direction away from the substrate 1, the sidewall of the pixel opening 201 formed on the pixel defining layer 2 can be set inclined, that is, the sidewall of the pixel opening 201 is a complete inclined surface.

Thus, while forming the light-emitting unit 22 of the display panel, the second electrode 8 of the light-emitting unit 22 of the display panel can form a continuous and uniform film on the sidewall of the pixel opening 201, thereby enabling the second electrode 8 to more effectively protect the pixel defining layer 2. During the patterning process of the light-emitting unit 22, the first electrode 3 of the light-emitting unit 22 is not easily damaged, thereby improving the display effect of the display panel.

Other solutions of the display panel in this embodiment are the same as those of the display panel in the above embodiments, and will not be repeated here.

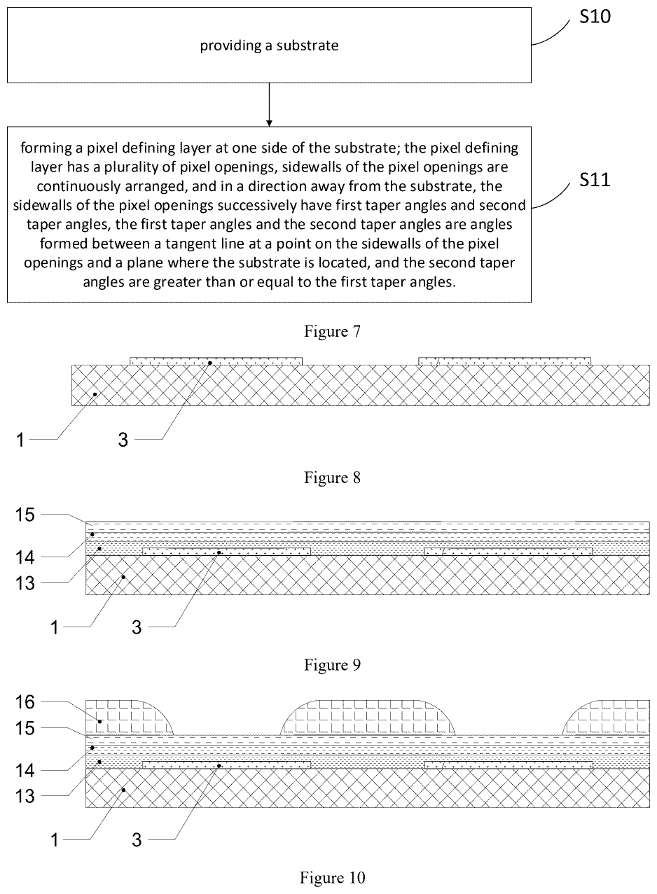

In some embodiments, please refer to FIG. 7, the present application also provides a method for preparing a display panel, and the method includes:

S10: providing a substrate 1.

S11: forming a pixel defining layer 2 at one side of the substrate 1; and the pixel defining layer 2 has pixel openings 201, sidewalls of the pixel openings 201 are continuously arranged, and along a direction away from the substrate 1, the sidewalls of the pixel openings 201 successively have first taper angles Q1 and second taper angles Q2, and the first taper angles Q1 and the second taper angles Q2 are angles formed between a tangent line at a point on the sidewalls of the pixel openings 201 and a plane where the substrate 1 is located, and the second taper angles Q2 are greater than or equal to the first taper angles Q1.

The sidewall of the pixel opening 201 of the display panel formed by the above method is a complete continuous surface. While forming the light-emitting unit of the display panel, the second electrode 8 of the light-emitting unit of the display panel can form a continuous and uniform film on the sidewall of the pixel opening 201, thereby enabling the second electrode 8 to more effectively protect the pixel defining layer 2. During the patterning process of the light-emitting unit, the first electrode 3 of the light-emitting unit is not easily damaged, thereby improving the display effect of the display panel.

In some embodiments, the step of forming a pixel defining layer 2 at one side of the substrate 1 includes:

Please refer to FIG. 8, forming a first electrode layer at one side of the substrate 1, and the first electrode layer includes multiple first electrodes 3 arranged at intervals.

Please refer to FIG. 9, successively forming a stacked first pixel defining material sublayer 13, second pixel defining material sublayer 14 and third pixel defining material sublayer 15 at one side of the substrate 1.

In one embodiment, a first pixel defining material sublayer 13 is formed at one side of the substrate 1 at a first deposition rate, and the first pixel defining material layer may be formed by deposition in a chamber with silane, ammonia and a low hydrogen content.

A second pixel defining material sublayer 14 is formed at a side of the first pixel defining material sublayer 13 away from the substrate 1 at a second deposition rate. The second pixel defining material sublayer 14 can be formed in a chamber with silane, ammonia, and nitrous oxide.

A third pixel defining material sublayer 15 is formed at a side of the second pixel defining material sublayer 14 away from the substrate 1 at a third deposition rate; and the first deposition rate is less than the second deposition rate, and the second deposition rate is less than the third deposition rate. The third pixel defining material sublayer 15 can be formed in a chamber with silane and nitrous oxide.

The content of an oxygen element in the second pixel defining sublayer 5 increases gradually, and the content of a nitrogen element decreases gradually. Thus, the properties of the second pixel defining sublayer 5 are between those of the first pixel defining material sublayer 13 and the third pixel defining material sublayer 15, resulting in better continuity of the inclined sidewall of the pixel opening 201 in the finally formed pixel defining layer 2.

The first pixel defining sublayer 4 is deposited at a relatively low deposition rate, therefore, the density of the first pixel defining sublayer 4 is relatively high, and the first pixel defining sublayer 4 can more effectively block moisture from the film layers of the substrate 1 from dispersing toward the isolation structure 9, thereby improving the problem of moisture affecting the morphology of the isolation structure 9, and ultimately further improving the connection effect between the second electrode 8 and the isolation structure 9.

Since the deposition rates of the first pixel defining material sublayer 13, the second pixel defining material sublayer 14 and the third pixel defining material sublayer 15 increase successively, the preparation efficiency of the pixel defining layer 2 can be improved while ensuring the moisture blocking effect of the pixel defining layer 2.

Please refer to FIG. 10, forming a patterned photoresist protection layer 16 at a side of the third pixel defining material sublayer 15 away from the substrate 1.

The photoresist protection layer 16 can protect the third pixel defining material sublayer 15.

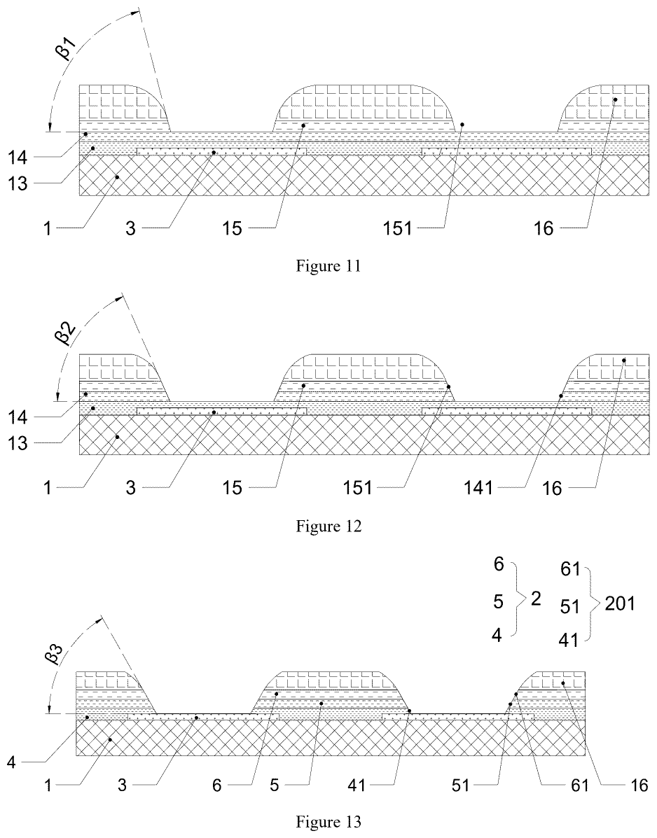

Please refer to FIG. 11, removing the third pixel defining material sublayer 15 not covered by the photoresist protection layer 16 using a first etching energy to form a first opening 151 exposing a portion of the second pixel defining material sublayer 14 on the third pixel defining material sublayer 15, and an angle between a sidewall of the first opening 151 and a side of the third pixel defining material sublayer 15 close to the substrate 1 is a first angle β1.

In an environment with a high sulfur hexafluoride content, after etching away the third pixel defining material sublayer 15 not covered by the photoresist protection layer 16 with a higher material etching selectivity ratio, a first opening 151 exposing a portion of the second pixel defining material sublayer 14 will form on the third pixel defining material sublayer 15. At this time, the inclination angle of the sidewall of the first opening 151 is the first angle β1.

Please refer to FIG. 12, removing the second pixel defining material sublayer 14 exposed by the first opening 151 using a second etching energy, while simultaneously removing a portion of the third pixel defining material sublayer 15 and a portion of the photoresist protection layer 16 facing the first opening 151, to form a second opening 141 exposing a portion of the first pixel defining material sublayer 13 on the second pixel defining material sublayer 14. An angle between the sidewalls of the first opening 151 and the second opening 141 and a side of the second pixel defining material sublayer 14 close to the substrate 1 is a second angle β2, where the second angle β2 is less than the first angle β1, and the second etching energy is less than the first etching energy.

In an environment with a medium sulfur hexafluoride content, the second pixel defining material sublayer 14 exposed by the first opening 151 is etched away with a medium material etching selectivity ratio. During the etching process of the second pixel defining material sublayer 14, a portion of the photoresist protection layer 16 facing the first opening 151 will be removed. After removing a portion of the photoresist protection layer 16, a portion of the third pixel defining material sublayer 15 facing the first opening 151 will be exposed, and then the exposed portion of the third pixel defining material sublayer 15 will be etched away, finally forming a second opening 141 exposing a portion of the first pixel defining material sublayer 13 on the second pixel defining material sublayer 14.

During this process, the first opening 151 on the third pixel defining material sublayer 15 will be further enlarged, and the sidewall of the first opening 151 of the third pixel defining material sublayer 15 is adjusted for the first time, making the sidewalls of the first opening 151 and the second opening 141 lie on the same inclined surface. The first angle β1 of the sidewall of the first opening 151 becomes smaller to form the second angle β2. At this time, the inclination angle of the sidewalls of the first opening 151 and the second opening 141 is the second angle β2.

Please refer to FIG. 13, removing the first pixel defining material sublayer 13 exposed by the second opening 141 using a third etching energy, while simultaneously removing a portion of the third pixel defining material sublayer 15, a portion of the second pixel defining material sublayer 14 and a portion of the photoresist protection layer 16 facing the first opening 151, to form a pixel defining layer 2 including a pixel opening 201. An angle between the sidewall of the pixel opening 201 and a side of the first pixel defining sublayer 4 close to the substrate 1 is a third angle β3, where the third angle β3 is less than the second angle β2, and the third etching energy is less than the second etching energy.

In an environment with a low sulfur hexafluoride content and an increased oxygen flow, the first pixel defining material sublayer 13 exposed by the second opening 141 is etched away with a lower material etching selectivity ratio. During the etching process of the first pixel defining material sublayer 13, a portion of the photoresist protection layer 16 facing the first opening 151 will be removed. After removing a portion of the photoresist protection layer 16, a portion of the third pixel defining material sublayer 15 and the second pixel defining material sublayer 14 facing the first opening 151 will be exposed, and then the exposed portion of the third pixel defining material sublayer 15 and the second pixel defining material sublayer 14 will be etched away, finally forming a first pixel sub-opening 41 on the first pixel defining material sublayer 13.

During this process, the first opening 151 on the third pixel defining material sublayer 15 will be enlarged again, the sidewall of the first opening 151 of the third pixel defining material sublayer 15 is adjusted again, the second opening 141 on the second pixel defining material sublayer 14 will be enlarged, and the sidewall of the second opening 141 of the second pixel defining material sublayer 14 is adjusted, making the first opening 151 form a third pixel sub-opening 61 and the second opening 141 form a second pixel sub-opening 51. The sidewalls of the third pixel sub-opening 61, the second pixel sub-opening 51 and the first pixel sub-opening 41 lie on the same inclined surface, making the second angle β2 of the sidewalls of the third pixel sub-opening 61 and the second pixel sub-opening 51 become smaller to form the third angle β3. At this time, the inclination angle of the sidewall of the pixel opening 201 composed of the third pixel sub-opening 61, the second pixel sub-opening 51 and the first pixel sub-opening 41 is the third angle β3.

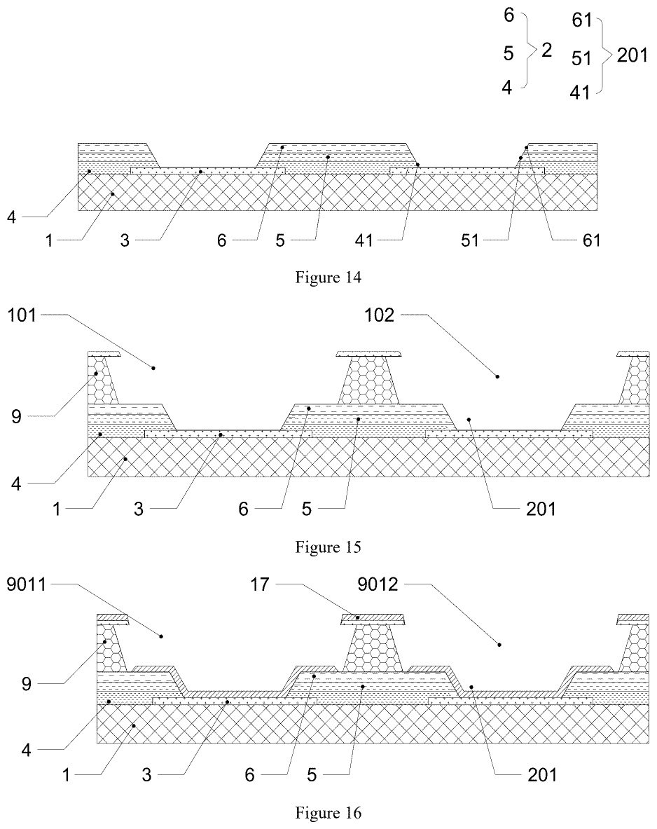

Please refer to FIG. 14, removing the photoresist protection layer 16. The sidewall of the pixel opening 201 formed by the above method is more easily made into a continuous inclined surface.

In some embodiments, after the step of forming the pixel defining layer 2 at one side of the substrate 1, the method further includes:

Please refer to FIG. 15, forming an isolation structure 9 at a side of the pixel defining layer 2 away from the substrate 1, and the isolation structure 9 is enclosed to form an isolation opening 901, and the isolation opening 901 communicates with the pixel opening 201. The isolation opening 901 includes a first isolation opening 9011 and a second isolation opening 9012.

Please refer to FIG. 16, forming a light-emitting material layer 17 of a first light-emitting unit in the first isolation opening 9011, and the light-emitting material layer 17 of the first light-emitting unit extends to a side of the isolation structure 9 away from the substrate 1 and extends to the sidewall of the pixel opening 201.

The light-emitting material layer 17 will break at the isolation structure 9, making at least a portion of the light-emitting material layer 17 located in the isolation opening 901 form a light-emitting portion 7. By controlling the deposition angle, the light-emitting portion 7 can be made not to contact the isolation structure 9.

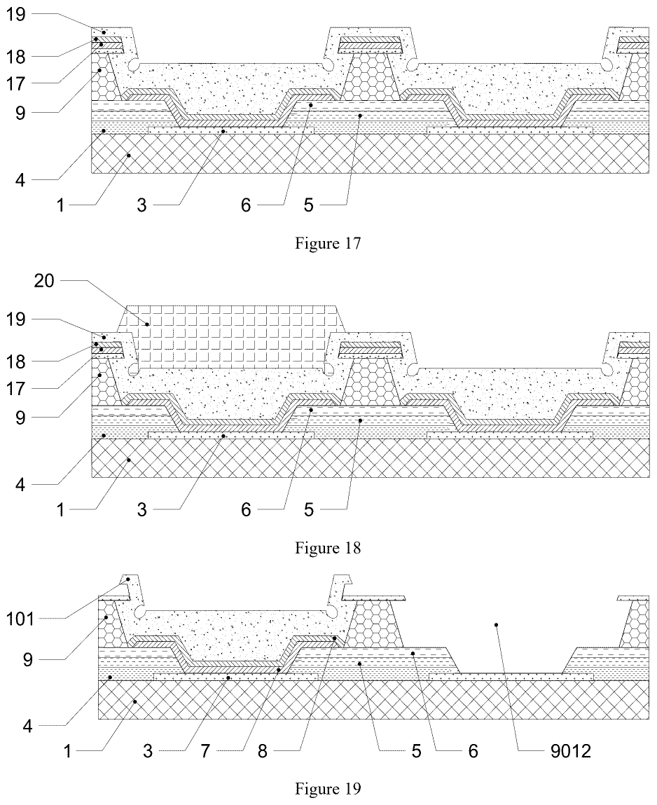

Please refer to FIG. 17, successively forming a second electrode material layer 18 and a first encapsulation material layer 19 at a side of the light-emitting material layer 17 of the first light-emitting unit away from the substrate 1.

The second electrode material layer 18 will break at the isolation structure 9, making at least a portion of the second electrode material layer 18 located in the isolation opening 901 form a second electrode 8. By controlling the deposition angle, the second electrode 8 can extend from inside the isolation opening 901 to make an electrical contact with the isolation structure 9, to connect adjacent second electrodes 8 or connect the second electrode 8 to other circuits. Thus, the manufacturing difficulty of the display panel can be reduced.

Since the sidewall of the pixel opening 201 is a continuous inclined surface, a continuous and uniform second electrode material layer 18 can be formed on the sidewall of the pixel opening 201 corresponding to the second isolation opening 9012.

Please refer to FIG. 18, forming a first etching barrier layer 20 at a side of the first encapsulation material layer 19 of the first light-emitting unit away from the substrate 1 in the first isolation opening 9011, and an orthographic projection of the first etching barrier layer 20 on the substrate 1 covers an orthographic projection of the first isolation opening 9011 on the substrate 1 and covers a portion of an orthographic projection of the isolation structure 9 on the substrate 1.

The first etching barrier layer 20 can protect the corresponding light-emitting material layer 17, second electrode material layer 18 and first encapsulation material layer 19 of the first light-emitting unit.

Please refer to FIG. 19, removing the first encapsulation material layer 19, the second electrode material layer 18 and the light-emitting material layer 17 of the first light-emitting unit not covered by the first etching barrier layer 20, and removing the first etching barrier layer 20, to form a light-emitting portion 7, a second electrode 8 and a first encapsulation unit 101 of the first light-emitting unit in the first isolation opening 9011, and the second electrode 8 extends to electrically connect with the isolation structure 9 corresponding to the first light-emitting unit.

After removing the first encapsulation material layer 19, the light-emitting material layer 17 and the second electrode material layer 18 not covered by a first etching protection layer, the first electrode 3, the light-emitting portion 7 of the first light-emitting unit and the second electrode 8 form a first light-emitting unit, and the first light-emitting unit is completely covered by the first encapsulation unit 101, thereby reducing the risk of deposition materials entering deposition equipment after exposure to air, causing equipment contamination and film layer breakage.

Thus, without requiring a precise mask, the light-emitting portion 7, the second electrode 8 and the first encapsulation unit 101 can be formed only in the first isolation opening 9011, and the second electrode 8 can be electrically connected to the isolation structure 9, thereby forming the first light-emitting unit in the first isolation opening 9011 at a lower cost.

Since a continuous and uniform second electrode material layer 18 can be formed on the sidewall of the pixel opening 201 corresponding to the second isolation opening 9012, during the process of removing the first encapsulation material layer 19 of the first light-emitting unit not covered by the first etching barrier layer 20, the second electrode material layer 18 can better protect the pixel defining layer 2 and the first electrode 3 corresponding to the second isolation opening 9012, thereby making it not easy to form recesses 203 at the side of the pixel defining layer 2 corresponding to the second isolation opening 9012 away from the substrate 1, and not easy to damage the first electrode 3 corresponding to the second isolation opening 9012.

Forming a second light-emitting unit and a second encapsulation unit 102 disposed at a side of the second light-emitting unit away from the substrate 1 in the second isolation opening 9012.

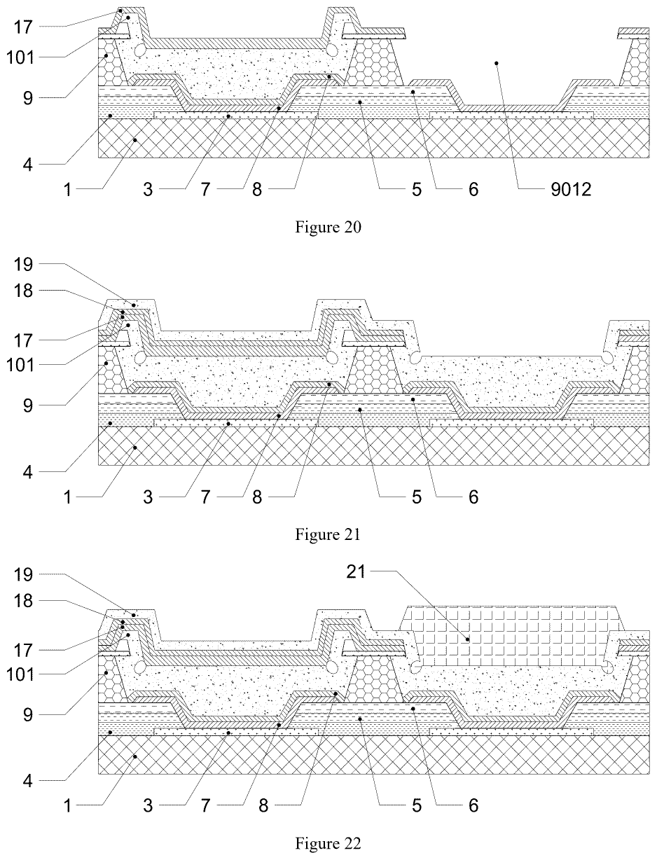

In one embodiment, please refer to FIG. 20, forming a light-emitting material layer 17 of the second light-emitting unit in the second isolation opening 9012, and the light-emitting material layer 17 of the second light-emitting unit extends to a side of the isolation structure 9 away from the substrate 1.

Please refer to FIG. 21, successively forming a second electrode material layer 18 and a first encapsulation material layer 19 at a side of the light-emitting material layer 17 of the second light-emitting unit away from the substrate 1.

Please refer to FIG. 22, forming a second etching barrier layer 21 at a side of the first encapsulation material layer 19 of the second light-emitting unit away from the substrate 1 in the second isolation opening 9012, and an orthographic projection of the second etching barrier layer 21 on the substrate 1 covers an orthographic projection of the second isolation opening 9012 on the substrate 1 and covers a portion of an orthographic projection of the isolation structure 9 on the substrate 1.

Please refer to FIG. 5 again, removing the first encapsulation material layer 19, the second electrode material layer 18 and the light-emitting material layer 17 of the second light-emitting unit not covered by the second etching barrier layer 21, and removing the second etching barrier layer 21, to form a light-emitting portion 7, a second electrode 8 and a second encapsulation unit 102 of the second light-emitting unit in the second isolation opening 9012, and the second electrode 8 extends to electrically connect with the isolation structure 9 corresponding to the second light-emitting unit.

Since during the formation process of the first light-emitting unit, recesses 203 are not easily formed at the side of the pixel defining layer 2 corresponding to the second isolation opening 9012 away from the substrate 1, the connection effect between the second electrode 8 of the second light-emitting unit and the corresponding isolation structure 9 is better.

Since during the formation process of the first light-emitting unit, the first electrode 3 corresponding to the second isolation opening 9012 is not easily damaged, the yield of the second light-emitting unit can be improved, ultimately improving the dark spot issue of the display panel, thereby enhancing the display effect of the display panel.

In some embodiments, the present application also provides an electronic device, and the electronic device includes the display panel in the present application, or includes a display panel prepared by the preparation method of the display panel in the present application. The electronic device may include a device with image processing capabilities, such as a server, a personal computer, a laptop, etc. Since the electronic device includes the display panel in the present application, the display effect of the electronic device is better.

The above embodiments can be combined. For the sake of brevity, not all combinations of the features in the above embodiments have been described. However, as long as these combinations do not conflict, they should all be considered as falling within the scope recorded in this specification.

The above-described embodiments only express several implementation methods of the present application. Their descriptions are relatively specific and detailed, but they should not be understood as limitations on the patent scope of the application. It should be pointed out that for ordinary technicians in the field, without departing from the concept of the present application, several modifications and improvements can still be made, which all belong to the protection scope of the present application. Therefore, the protection scope of the present application patent should be subject to the attached claims.

What is claimed is:

1. A display panel, wherein the display panel comprises:
a substrate;
a pixel defining layer, disposed on one side of the substrate and provided with a plurality of pixel openings, wherein sidewalls of the pixel openings are arranged continuously, and in a direction away from the substrate, the sidewalls of the pixel openings sequentially have a first taper angle and a second taper angle, wherein the first taper angle and the second taper angle are angles formed between a tangent line at a point on the sidewall of the pixel opening and a plane where the substrate is located, and the second taper angle is greater than or equal to the first taper angle; and
an isolation structure, disposed on a side of the pixel defining layer away from the substrate, wherein the isolation structure is enclosed to form isolation openings, and the isolation openings communicate with the pixel openings.

2. The display panel according to claim 1, wherein the pixel defining layer comprises a first pixel defining sublayer and a second pixel defining sublayer arranged in a direction away from the substrate, wherein the first pixel defining sublayer is provided with first pixel sub-openings, the second pixel defining sublayer is provided with second pixel sub-openings, the sidewalls of the first pixel sub-opening have first sub-taper angles, the sidewalls of the second pixel sub-opening have second sub-taper angles, the second sub-taper angles on the second pixel defining sublayer are greater than or equal to the first sub-taper angles on the first pixel defining sublayer, and in a thickness direction of the substrate, regions of the second pixel sub-openings cover regions of the first pixel sub-openings.

3. The display panel according to claim 2, wherein the pixel defining layer further comprises a third pixel defining sublayer disposed on the side of the second pixel defining sublayer away from the substrate, wherein the third pixel defining sublayer is provided with third pixel sub-openings, sidewalls of the third pixel sub-openings have third sub-taper angles, the third sub-taper angles on the third pixel defining sublayer are greater than or equal to the second sub-taper angles on the second pixel defining sublayer, and in the thickness direction of the substrate regions of the third pixel sub-openings cover regions of the second pixel sub-openings.

4. The display panel according to claim 3, wherein etching selectivity ratios of materials of the first pixel defining sublayer, the second pixel defining sublayer and the third pixel defining sublayer decrease in sequence.

5. The display panel according to claim 4, wherein densities of the first pixel defining sublayer, the second pixel defining sublayer and the third pixel defining sublayer decrease in sequence.

6. The display panel according to claim 4, wherein a material of the first pixel defining sublayer comprises silicon nitride.

7. The display panel according to claim 4, wherein in a direction from the first pixel defining sublayer to the third pixel defining sublayer, at least two layers of the pixel defining layer comprise an oxygen element, and the content of the oxygen element increases gradually;
or, in the direction from the first pixel defining sublayer to the third pixel defining sublayer, the content of a nitrogen element in the pixel defining layer decreases gradually.

8. The display panel according to claim 4, wherein in the thickness direction of the substrate, a thickness of the pixel defining layer is greater than or equal to 2000 Å and less than or equal to 6000 Å.

9. The display panel according to claim 1, wherein the display panel further comprises: a light-emitting unit, at least partially disposed in the isolation openings; an encapsulation unit, disposed on a side of the light-emitting unit away from the substrate, wherein at least part of the encapsulation unit extends from a side surface of the isolation structure facing the isolation openings to a side of the isolation structure away from the substrate.

10. The display panel according to claim 9, wherein adjacent encapsulation units are spaced apart or overlapped with each other on the side of the isolation structure away from the substrate.

11. The display panel according to claim 9, wherein there is a gap between the encapsulation unit disposed on the side of the isolation structure away from the substrate and the side of the isolation structure away from the substrate.

12. The display panel according to claim 9, wherein the display panel further comprises a second encapsulation layer disposed on a side of the encapsulation unit away from the substrate and a third encapsulation layer disposed on a side of the second encapsulation layer away from the substrate.

13. The display panel according to claim 12, wherein materials of both the encapsulation unit and the third encapsulation layer comprise inorganic materials; a material of the second encapsulation layer comprises an organic material.

14. The display panel according to claim 12, wherein the isolation structure comprises a first isolation portion and a second isolation portion stacked in sequence in the direction away from the substrate, wherein the second isolation portion is disposed on the first isolation portion and extends outward along a sidewall of the first isolation portion.

15. The display panel according to claim 12, wherein the light-emitting unit comprises a first electrode, a light-emitting portion and a second electrode stacked in sequence in the direction away from the substrate, wherein the pixel openings expose part of the first electrode.

16. A display panel, wherein the display panel comprises:
a substrate;
a pixel defining layer, disposed on one side of the substrate; wherein the pixel defining layer comprises pixel openings, and in a direction away from the substrate, the pixel defining layer comprises a plurality of stacked pixel defining sublayers, wherein etching selectivity ratios of materials of the multiple pixel defining sublayers decrease in sequence in the direction away from the substrate;
an isolation structure, disposed on a side of the pixel defining layer away from the substrate, wherein the isolation structure encloses to form isolation openings, and the isolation openings communicate with the pixel openings.

17. The display panel according to claim 16, wherein the pixel defining layer comprises a first pixel defining sublayer, a second pixel defining sublayer and a third pixel defining sublayer stacked in sequence along the direction away from the substrate.

18. The display panel according to claim 17, wherein densities of the first pixel defining sublayer, the second pixel defining sublayer and the third pixel defining sublayer decrease in sequence.

19. The display panel according to claim 18, wherein in a direction from the first pixel defining sublayer to the third pixel defining sublayer, at least two layers in the pixel defining layer comprise an oxygen element, and a content of the oxygen element increases gradually;
or, in the direction from the first pixel defining sublayer to the third pixel defining sublayer, at least two layers of the pixel defining layer comprise a nitrogen element, and a content of the nitrogen element decreases gradually.

20. An electronic device, wherein the electronic device comprises the display panel of claim 1.
